(19) United States
(12) Patent Application Publication
(10) Pub. No.: US 2015/0223353 A1
(43) Pub. Date: Aug. 6, 2015

(54) UNIVERSAL TABLET STAND

(71) Applicant: Donald Reinauer, Sheffield, MA (US)

(72) Inventor: Donald Reinauer, Sheffield, MA (US)

(21) Appl. No.: 14/174,129

(22) Filed: Feb. 6, 2014

(51) Int. Cl. H05K 5/02; F16M 11/22; H05K 5/00

(52) U.S. Cl. CPC H05K 5/0204; H05K 5/0086; F16M 11/22

(57) ABSTRACT

A stand for an electronic device. The stand having a first surface, a second surface forming an acute angle with respect to the first surface, a third surface substantially perpendicular with the second surface; and two side surfaces facing each other, wherein each of the two side surfaces is shaped substantially as a right triangle, and Wherein an adhesive material is attached on at least one of the first surface, the second surface, or the third surface.

### TECHNICAL FIELD

Exemplary embodiments of the present invention concern stands for electronic devices, and more specifically, stands for tablet computing devices.

### DISCUSSION OF RELATED ART

Recent advances in electronics have led to the development of mobile computing devices, such as tablet PCs and mobile phones. Such devices are portable and may be carried from one location to another. During use, such devices are typically placed on a desktop or other flat support surface, and the display of the electronic device is placed in an inclined position for ease of viewing via some stand or support structure. Several types of stands for tablets are commercially available in the market. Most if not all of the commercially available stands provide an inclined surface upon which a tablet can be rested, coupled with a slot at the bottom to receive the bottom portion of the tablet.

### SUMMARY

According to an exemplary embodiment of the present invention, there is provided a stand for an electronic device. The stand may be shaped substantially as a pentahedron. The stand includes a first surface. A second surface forms an acute angle with respect to the first surface. A third surface is substantially perpendicular with the second surface. Two side surface face each other. The first surface, the second surface, and the third surface each are shaped as a rectangle. The two side surfaces each are shaped substantially as a right-angled triangle. A sticky material is attached on at least one of the first surface, the second surface, or the third surface.

The sticky material may be a Velcro strip.

The stand may have a hollow body.

The stand may have an uneven weight distribution.

A portion of the stand, which is closer to the third surface, may be relatively heavier than an upper portion of the stand.

The stand may further comprise a light fixture and a battery holder.

### BRIEF DESCRIPTION OF THE DRAWINGS

A more complete appreciation of the present disclosure and any of the attendant aspects thereof will he readily obtained as the same becomes better understood by reference to the following detailed description when considered in connection with the accompanying drawings, wherein:

FIG. 1 is a perspective view illustrating a set of support stands for an electronic device according to an exemplary embodiment of the present invention;

FIG. 2 is a front view illustrating a support stand for an electronic device according to an exemplary embodiment of the present invention;

FIG. 3 is a rear view illustrating a support stand for an electronic device according to an exemplary embodiment of the present invention;

FIG. 4 is a side view illustrating a support stand for an electronic device according to an exemplary embodiment of the present invention;

FIG. 5 is a perspective view illustrating the application of a set of support stands to a tablet, according to an exemplary embodiment of the present invention;

FIG. 6 is a perspective view illustrating the application of a set of support stands to a tablet in another orientation, according to an exemplary embodiment of the present invention;

FIG. 7 is a perspective view illustrating the application of a set of support stands to a tablet at a different supporting angle, according to an exemplary embodiment of the present invention;

FIG. 8 is a perspective view illustrating the application of a set of support stands at a different supporting angle to a tablet in another orientation, according to an exemplary embodiment of the present invention;

FIG. 9 is a perspective view illustrating the application of a support stand to a tablet, according to an exemplary embodiment of the present invention;

FIG. 10 is a perspective view illustrating the application of a support stand to a tablet in another orientation, according to an exemplary embodiment of the present invention; and

FIG. 11 is a flowchart illustrating a method of forming a support stand.

### DETAILED DESCRIPTION OF EMBODIMENTS

Hereinafter, exemplary embodiments of the inventive concept will be described in detail with reference to the accompanying drawings. The inventive concept, however, may be modified in various different ways, and should not be construed as limited to the embodiments set forth herein. Like reference numerals may be used to denote the same or substantially the same elements throughout the specification and the drawings. As used herein, the singular forms “a,” “an,” and “the” are intended to include the plural forms as well, unless the context clearly indicates otherwise. It will be understood that when an element or layer is referred to as being “on,” “connected to,” “coupled to,” or “adjacent to” another element or layer, it can be directly on, connected, coupled, or adjacent to the other element or layer, or intervening elements or layers may be present.

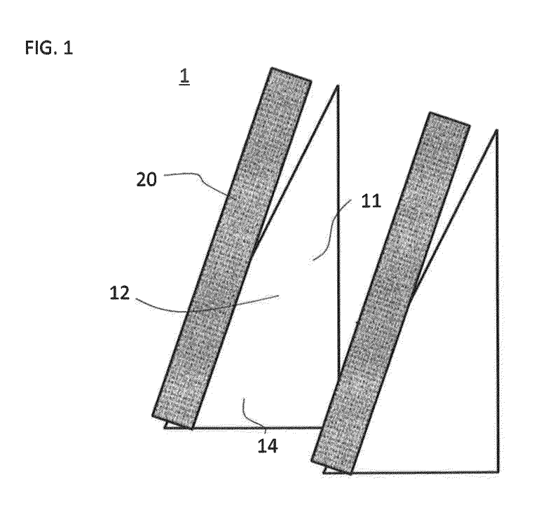

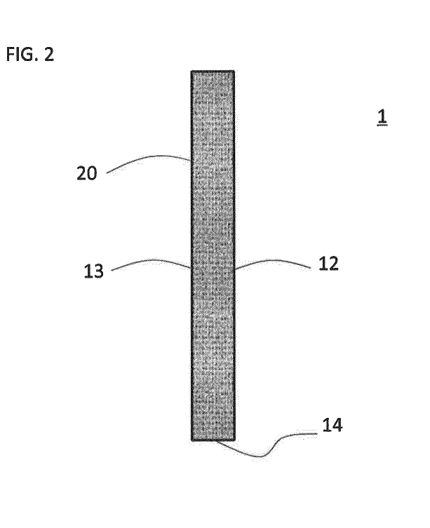

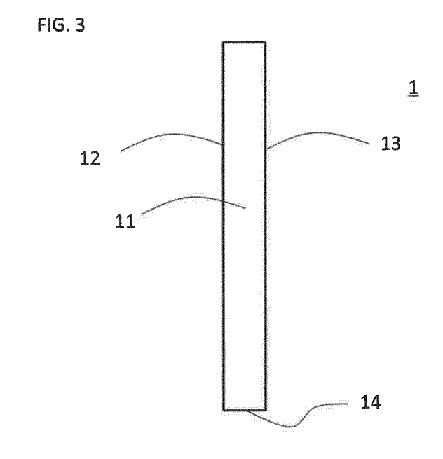

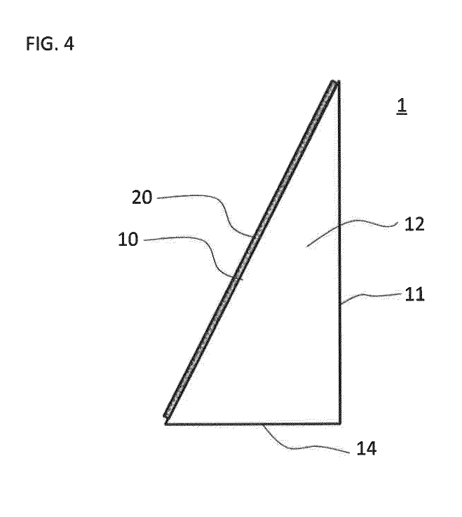

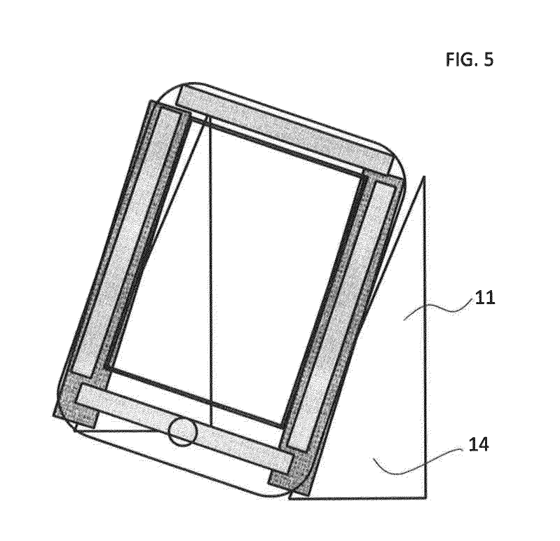

FIG. 1 is a perspective view illustrating a set of support stands for an electronic device according to an exemplary embodiment of the present invention. FIG. 2 is a front view illustrating a support stand for an electronic device according to an exemplary embodiment of the present invention. FIG. 3 is a rear view illustrating a support stand for an electronic device according to an exemplary embodiment of the present invention. FIG. 4 is a side view illustrating a support stand for an electronic device according to an exemplary embodiment of the present invention. FIG. 5 is a perspective view illustrating the application of a set of support stands to a tablet, according to an exemplary embodiment of the present invention.

Referring to FIGS. 1 to 4, the support stand 1 may be shaped as a triangular block that includes a front surface 10, a rear surface 11, a first side surface 12, a second side surface 13, and a bottom surface 14. As shown, the front surface 10, the rear surface 11, and the bottom surface 14 form a triangle, with the rear surface 11 having a longer length than the bottom surface 14 and forming an angle between them that is 90 degrees or substantially 90 degrees.

A first securing medium 20 is attached onto the front surface. The first securing medium 20 may be an adhesive, or a Velcro strip having tiny hooks on one surface. The other surface of the Velcro strip can be applied with an adhesive to securely attach onto the front surface of stand 1.

A second securing medium may be applied onto a back surface of a tablet. The second securing medium is made with a material that can be releaseably attached to the first securing medium. In at least the present embodiment, the second securing medium is also a Velcro strip. The second Velcro strip may have dense loops on a surface and an adhesive on the other surface thereof.

Referring to FIG. 5, the second securing medium or strips of Velcro are adhered to a surface of a tablet, near each of the tablet's edges. When the first Velcro strip 20 of each of the set of stands 1 is pressed upon opposing edge portions of the tablet having the second securing medium, the hooks of the first Velcro strip 20 catch onto the loops of the second Velcro strip, and thus the tablet is fastened to the stands, presenting the display at an angle for viewing.

Although in the above example the first Velcro strip 20 has hooks and the second Velcro strip has loops, exemplary embodiments of the present invention are not limited thereto. Alternatively, the first Velcro strip 20 may have hoops, and the second Velcro strip may have hooks.

The rear surface 11 of the support stand 1 is flat and even and is substantially perpendicular with. the bottom surface 14. The first side surface 12 of the support stand 1 is shaped substantially as a right-angled triangle. The second side surface 13 is opposite the first side surface 12 and may have substantially the same shape as the first side surface 12. Thus, the shape of side 12 or 13 is a right triangle or a slightly obtuse or acute triangle.

The first side surface 12 and the second side surface 13 are positioned between the front surface 10 and the rear surface 11.

The bottom surface 14 of the support stand 1 can be placed on a desktop or other substantially flat support surfaces.

According to an embodiment of the present invention as shown in FIG. 5, the stands 1 are shaped and dimensioned to position the tablet at a more upright angle, suitable for viewing when the sites of the reader all more level with the tablet, such as when the reader reads from the tablet when lying down in bed. In such instances, the tablet mounted on the stands would be placed on the body of the reader. I have found that a dimension of 6.25×2.25×6.625 in inches as perimeter of the triangle side 12 of stand 1 provides a very comfortable viewing angle for the reader in such a position. In other words, a substantially right triangular block having a first longest length at (10), a slightly shorter length, by less than 5% difference from the first longest length at (11), and a third length that is shorter at a length less than 35% of the first longest length at (14).

In other embodiments, the inclination of the electronic device may be adjusted by the angle formed between the front surface 10 and the bottom surface 14. Depending on a user's convenience, the stand 1 may be fabricated to have various different angles between the front surface 10 and the 14. In still other embodiments, the lengths that form the perimeter of flat side 12 can be proportionally lengthen or shorten to match the different sizes of the handheld devices such as tablets, mini-tablets, or smartphones.

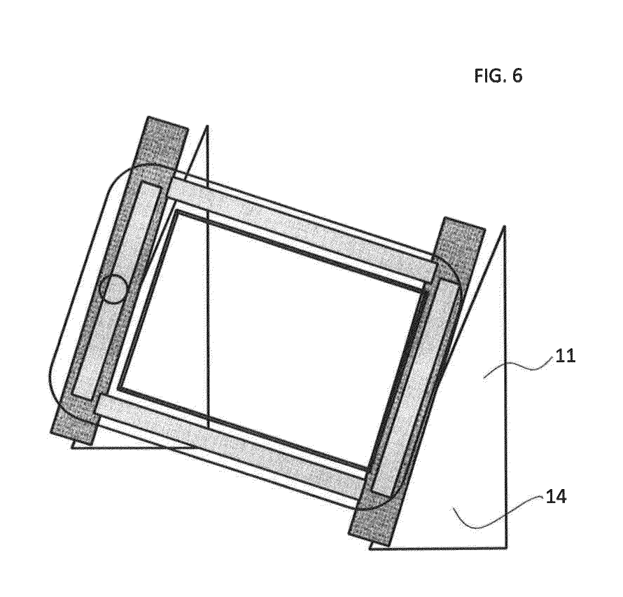

FIG. 6 is a perspective view illustrating the application of a set of support stands to a tablet in another orientation, according to an exemplary embodiment of the present invention.

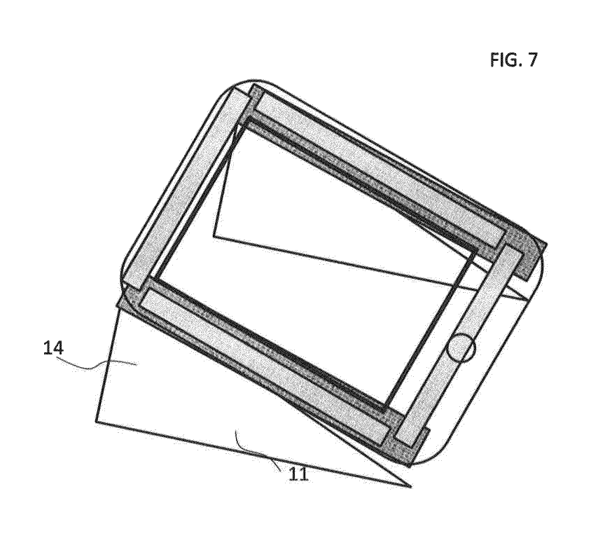

FIG. 7 is a perspective view illustrating the application of a set of support stands at a shallower viewing angle, by positioning the rear surface 11 on the bottom, according to another exemplary embodiment of the present invention.

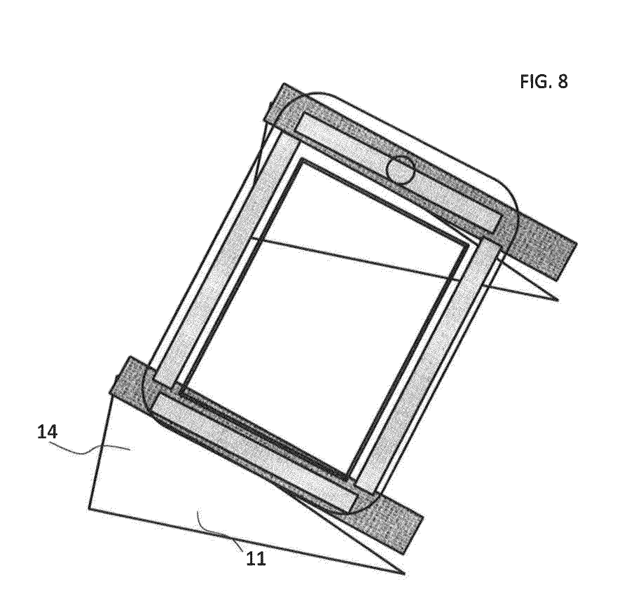

FIG. 8 is a perspective view illustrating the application of a set of support stands at a different supporting angle to a tablet in another orientation, according to an exemplary embodiment of the present invention.

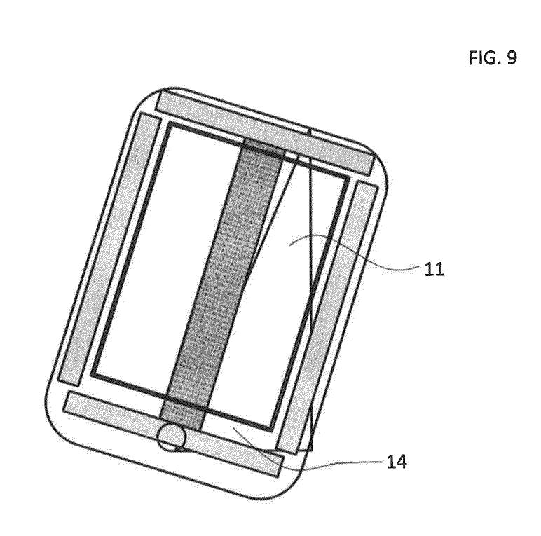

FIG. 9 is a perspective view illustrating the application of a support stand to a tablet, according to an exemplary embodiment of the present invention. Note in this embodiment, only a single stand 1 is used. A user can readily appreciate that the second securing medium or Velcro strips can be applied across the midsection of the tablet as opposed to on the edge portions, to provide a more secure attachment to stand 1.

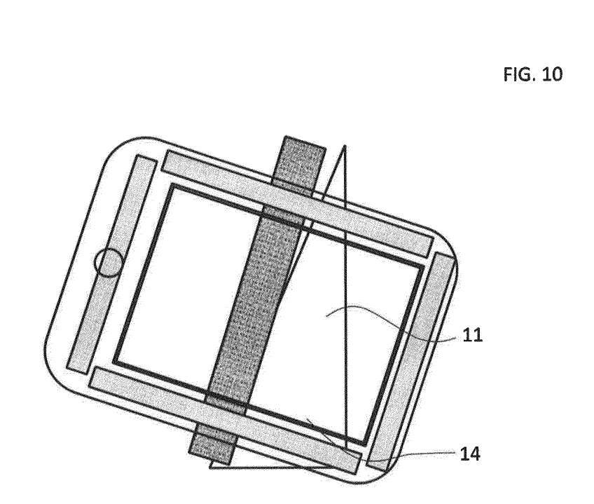

FIG. 10 is a perspective view illustrating the application of a support stand to a tablet in another orientation, according to an exemplary embodiment of the present invention;

In the above-described example, the first Velcro strip 20 is attached only on the front surface 10 of stand 1. However, exemplary embodiments of the present invention are not limited thereto. For example, a Velcro strip may be attached on the rear surface 11 of the support stand 1. in this case, the electronic device may stand in a right angle with respect to the bottom surface 14. Alternatively, a Velcro strip may be put on the bottom surface 14. In this situation, the rear surface 11 may function in fact as a bottom surface, and thus, an electronic device may be placed substantially at a right angle with respect to the flat surface 12. In another alternative embodiment, a Velcro strip may be put on the flat surface 12. In this situation, a tablet can be attached and supported by the flat surface 12.

The support stand 1 and the securing medium 20 may have various colors and may he sized and dimensioned to match an electronic device which it is to be used for. The support stand 1 may have a hollow body, thus leading to the support stand 1 being lightweight. The support stand 1 may be made of plastic or other light weight and inexpensive material.

Although in the above example the tablet PC is used as the electronic device by way of example, exemplary embodiments of the present invention are not limited thereto. Other various types of electronic devices including a cell phone, a smart phone, a laptop computer, etc., may also be supported by the support stand 1.

According to an exemplary embodiment of the present invention, the support stand 1 may include an LED (Light Emitting Diode) bulb with accompanying fixture and a battery, which provides aesthetics as well as lighting in a dark surrounding.

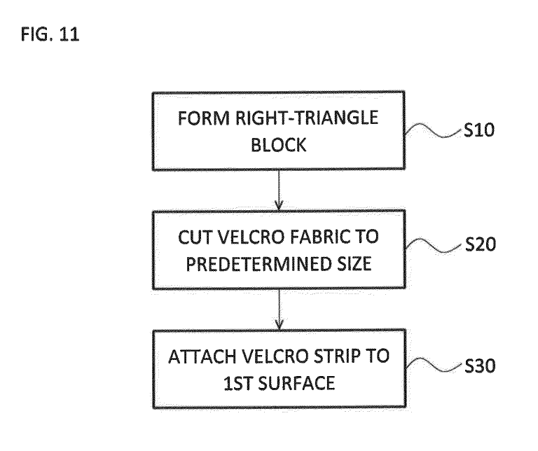

FIG. 11 is a flowchart illustrating a method of manufacturing a support stand according to an exemplary embodiment of the present invention.

Referring to FIG. 11, color coordinated plastic is melted into a mold and is then cooled, forming a pentahedron as shown in FIG. 1 (S10). The mold may be sized and dimensioned to fit the size of an electronic device for which a set of support stands 1 is to be used. The company logo of an electronic device to be used alongside the support stand 1 may be previously engraved inside the mold, and thus, appear on a surface of the formed support stand 1 thereof. The mold may also have a space that allows a light fixture and a battery holder to be formed in the support stand 1.

A Velcro fabric is cut to the size of the front surface 10 of the support stand 1, thus forming the first Velcro strip 20 and second Velcro strip (S20). The first Velcro strip 20 is then attached onto the front surface 10 of the support stand 1 (S30).

The second Velcro strip is attached onto a surface (e.g., back surface) of an electronic device. When the first Velcro strip 20 and the second Velcro strip are attached together, the electronic device may be securely placed on the underneath floor in an inclined position.

While the inventive concept has been shown and described with reference to exemplary embodiments thereof, it will be apparent to those of ordinary skill in the art that various changes in form and detail may be made thereto without departing from the spirit and scope of the inventive concept as defined by the following claims.

What is claimed is:

1. A stand for supporting an electronic device, comprising:
a free standing block shaped in a right triangle; and
a first securing medium attached to an inclined surface of the block, the securing medium is configured to releaseably attach to a mating securing medium.

2. The stand of claim 1, wherein the first securing medium is a Velcro strip.

3. The stand of claim 1, wherein the block has a hollow body.

4. The stand of claim 1, further comprising a light fixture and a battery holder.

5. A stand for an electronic device, comprising:
a first surface;
a second surface forming an acute angle with respect to the first surface,
a third surface substantially perpendicular with the second surface; and
two side surfaces facing each other, wherein each of the two side surfaces is shaped substantially as a right triangle, and wherein an adhesive material is attached on at least one of the first surface, the second surface, or the third surface.

6. The stand of claim 5, wherein the first, second, and third surfaces and the two side surfaces form a substantially right triangular block having a first longest length, a slightly shorter second length, by less than 5% difference from the first longest length, and a third length that is less than 35% of the first longest length.
